(19) United States
(12) Patent Application Publication
(10) Pub. No.: US 2024/0170451 A1
(43) Pub. Date: May 23, 2024

(54) ASSEMBLY OF INTEGRATED CIRCUIT WAFERS

(71) Applicant: STMicroelectronics (Crolles 2) SAS, Crolles (FR)

(72) Inventors: Come De Buttet, Lumbin (FR); Damien Jeanjean, Grenoble (FR); Sebastien Mermoz, Bernin (FR); Marc Neyens, Grenoble (FR)

(21) Appl. No.: 18/504,895

(22) Filed: Nov. 8, 2023

(30) Foreign Application Priority Data
Nov. 16, 2022 (FR) 2211895

(51) Int. Cl. H01L 23/00

(52) U.S. Cl. CPC H01L 24/83; H01L 24/08; H01L 2224/08145; H01L 2224/83047; H01L 2224/83895; H01L 2224/83896

(57) ABSTRACT

According to one aspect, there is proposed a method for assembling two integrated circuit wafers. The method includes removing by abrasion of a portion of an assembly face of a first wafer on a perimeter of the first wafer, and bonding the assembly face of the first wafer to an assembly face of a second integrated circuit wafer.

### CROSS-REFERENCE TO RELATED APPLICATIONS

This application claims the priority benefit of French patent application number 2211895, filed on Nov. 16, 2022, entitled “Assembly of Integrated Circuit Wafers,” which is hereby incorporated by reference to the maximum extent allowable by law.

### TECHNICAL FIELD

Embodiments and implementations relate to the manufacture of integrated circuits, in particular the assembly of integrated circuit wafers.

### BACKGROUND

The integrated circuit wafer assembly allows assembling two integrated circuit wafers by stacking them on top of each other.

In particular, each integrated circuit wafer is intended to contain several analog integrated circuits, or electronic chips, which are mutually separated by cutting lines.

In the remainder of the text, the term “wafer” might sometimes be used for simplification purposes instead of “integrated circuit wafer”.

Each integrated circuit wafer comprises a first “FEOL” (acronym of the expression “Front End Of Line”) portion in which the electronic components of the integrated circuits are formed. This semiconductor wafer can be made of silicon.

Each wafer also comprises a second “BEOL” (acronym of the expression “Back End Of Line”) portion including an interconnection network integrated in one or more dielectric layers. This “BEOL” portion extends from the FEOL portion to an assembly face of the wafer. The interconnection network comprises conductive tracks and/or conductive contacts on the assembly face of the wafer. The interconnection network allows transmitting electrical signals between the electronic components of the wafer to the conductive tracks and/or the conductive contacts on the assembly face of the wafer.

When the integrated circuit wafers are assembled, these wafers have their assembly faces assembled against each other.

The assembly of the integrated circuit wafers then have electronic structures called 3D electronic structures each including a chip from a first wafer assembled with a chip from a second wafer. The different 3D structures are mutually separated by the cutting lines.

Such a 3D structure allows reducing the lengths of the electrical interconnections between the different chips so as to improve its performance in terms of speed.

The assembly of the integrated circuit wafers can then be cut so as to obtain the different 3D structures each including two electronic chips stacked on top of each other.

The use of different integrated circuit wafers allows distributing functions of each chip of a 3D structure. A first wafer can in particular be used to produce integrated circuits implementing an analog portion of the electronic structures and a second wafer can be used to produce integrated circuits implementing a digital portion of the structures. For example, the first wafer of integrated circuits can be used to produce arrays of detectors of image sensors and the second wafer can be used to produce integrated circuits implementing a digital processing of the data generated from these arrays of detectors.

It is in particular possible to produce a hybrid bonding between the two wafers. The hybrid bonding allows creating dielectric-dielectric and metal-metal bonds between the assembly faces of the two wafers.

Each integrated circuit wafer has a perimeter laterally delimiting the wafer. In particular, each wafer has a main zone and a peripheral zone extending around the main zone to the perimeter of the wafer. The main zone of the wafer comprises all functional elements of the wafer, that is to say the different chips. The peripheral zone is itself devoid of functional elements.

The perimeter of each wafer can be rounded such that each wafer has an edge roll-off on the peripheral zone thereof. The edge roll-off corresponds to a drop in the height of the assembly face in the peripheral zone of the wafer relative to the main zone of the wafer.

The edge roll-off of each wafer prevents carrying out a satisfactory bonding of the wafers because the peripheral zones of the wafers are not in contact when the wafers are placed against each other.

In order to eliminate the edge roll-off of a wafer, it is conventional to cut a portion of the peripheral zone of the wafer to the perimeter thereof. This peripheral cutting, which corresponds to a mechanical trimming of the integrated circuit wafer in the peripheral zone thereof, is conventionally carried out by cutting tools such as cutting blades or wheels. This cutting thus allows obtaining a shoulder at a right angle at the cut. However, this cutting generates defects on the assembly face of the wafer at the cut. These defects may be fragments of the wafer which extend protruding from the assembly face. These defects do not allow immediately bonding the two wafers. Indeed, these defects can leave gaps between the two assembly faces of the wafers. The bonding cannot then be carried out correctly at these voids.

In order to remove the defects generated by the peripheral cutting, it is possible to carry out a chemical mechanical polishing (also known by the acronym “CMP”). Nevertheless, such a chemical mechanical polishing generates a slight edge roll-off at the shoulder obtained after cutting. In particular, the chemical mechanical polishing generates a chamfer on the shoulder obtained after cutting.

In order to eliminate this edge roll-off, it is common practice to bond the two wafers together on their assembly face then to perform a thermocompression to deform the integrated circuit wafer at the chamfer so that it is plated on the other integrated circuit wafer.

The assembly method may then comprise an anneal to seal the assembly.

Once the anneal has been performed, a control of the assembly can be carried out. Nevertheless, at this stage of the method, if assembly defects are identified, then the wafers cannot be peeled off and are therefore scrapped. Thus, assembly defects can be costly.

Moreover, such an assembly method has the drawback of comprising many steps, and is therefore relatively long to implement.

Moreover, the mechanical trimming of the integrated circuit wafer is only compatible with certain types of wafers. In particular, the mechanical trimming is not adapted for the integrated circuit wafers including an interconnection portion with extremely low dielectric constants (usually designated by the acronym “ULK BEOL” which means “Ultra Low-K Back-End Of Line”).

Thus, assembling two integrated circuit wafers in a simple and rapid manner would be advantageous.

### SUMMARY

According to one aspect, there is proposed a method for assembling two integrated circuit wafers, the method comprising: a removal by abrasion of a portion of an assembly face of a first integrated circuit wafer on a perimeter of the first wafer, and a bonding of the assembly face of the first wafer to an assembly face of a second integrated circuit wafer.

The removal by abrasion is carried out so as to hollow the perimeter of the integrated circuit wafer to limit, or even eliminate, an edge roll-off on a peripheral zone of the first integrated circuit wafer. The removal by abrasion may correspond for example to a polishing of a ridge on the assembly face of the first wafer.

Unlike a conventional cutting or trimming used to eliminate an edge roll-off, the removal by abrasion does not generate defects on the surface of the wafer.

The absence of defects on the surface of the wafer allows bonding the two wafers directly after said removal by abrasion. In addition, the bonding between the two wafers is improved.

Such a method therefore allows reducing the number of steps to be performed to assemble two integrated circuit wafers.

In an advantageous implementation, said removal by abrasion allows forming a peripheral hollow having a surface extending from the assembly face to the perimeter of the first wafer, the surface of the hollow having a rounded shape from the assembly face of the first wafer to a depth in the first wafer then being planar and parallel to the assembly face from this depth to the perimeter of the first integrated circuit wafer.

The depth is such that the hollow partially extends into the first portion and extends into the second portion of this first wafer.

In particular, the hollow is formed in a peripheral zone of the first integrated circuit wafer to the perimeter thereof. This peripheral zone extends around a main zone of the first integrated circuit wafer. The main zone of the first integrated circuit wafer includes functional elements of the first integrated circuit wafer, in particular electronic components and an interconnection network. The peripheral zone is devoid of functional elements of the first wafer.

Preferably, the surface of the hollow has, at the intersection between this surface and the assembly face, a tangent oriented relative to the assembly face at an angle comprised between 5 and 20 degrees.

Advantageously, the hollow extends from the perimeter of the integrated circuit wafer over a distance comprised between 1 and 4 mm.

In an advantageous implementation, the hollow is formed over a depth of comprised between 50 and 150 μm.

Preferably, the rounded shape of the hollow has a radius of curvature comprised between 1 and 10 mm, in particular in the range of 5 mm.

Advantageously, the removal by abrasion of the portion of the first integrated circuit wafer is carried out using at least one abrasive belt placed against the assembly face on the perimeter of the first integrated circuit wafer while driving the first integrated circuit wafer in rotation.

In an advantageous implementation, the surface of the abrasive belts has an abrasive face including abrasive diamonds.

Preferably, the bonding is a bonding by molecular adhesion.

Advantageously, the method further comprises a control of a conformity of the bonding.

Furthermore, controlling the bonding at this stage of the method allows avoiding implementing a thermocompression following the bonding. Indeed, the thermocompression which is conventionally used to improve the bonding of the two wafers is unnecessary here because the quality of the bonding has already been controlled.

In an advantageous implementation, the method further comprises an anneal following the bonding.

The anneal also allows sealing the assembly of the two wafers. The wafers can no longer be disassembled following this anneal.

In particular, the anneal can allow creating covalent bonds between the conductive tracks on the assembly face of the first integrated circuit wafer and the conductive tracks on the assembly face of the second integrated circuit wafer. The two integrated circuit wafers are then electrically connected.

Advantageously, the anneal is carried out after controlling the conformity of the bonding.

Controlling the bonding at this stage of the method allows detecting defects in the bonding while it is still possible to peel off the two integrated circuit wafers before repeating the bonding. Thus, the detection of bonding defects at this stage of the method allows avoiding scrapping the two bonded wafers.

Preferably, the method further comprises a control of the assembly of the two integrated circuit wafers after the anneal. This control allows checking the conformity of the assembly after anneal.

In an advantageous embodiment, each integrated circuit wafer comprises a first portion including electronic components and a second portion including interconnection networks integrated in one or more dielectric layers, the interconnection networks extending from said electronic components to the assembly face of the corresponding wafer, the interconnection networks of the two integrated circuit wafers being adapted to be electrically connected via the two assembly faces once the two integrated circuit wafers have been assembled.

According to another aspect, there is proposed an assembly of integrated circuit wafers obtained by the implementation of an assembly method as described previously.

According to yet another aspect, an assembly of two integrated circuit wafers is proposed, comprising a first integrated circuit wafer including an assembly face and a peripheral hollow having a surface extending from the assembly face to the perimeter of the first wafer, the surface of the hollow having a rounded shape from the assembly face of the first wafer to a depth in the first wafer then being planar and parallel to the assembly face from this depth to the perimeter of the first integrated circuit wafer.

The assembly also comprises a second integrated circuit wafer including an assembly face bonded to the assembly face of the first wafer.

According to one embodiment, the surface of the hollow has, at the intersection between this surface and the assembly face, a tangent oriented relative to the face at an angle comprised between 5 and 20 degrees.

According to one embodiment, the hollow extends from the perimeter of the first integrated circuit wafer over a distance comprised between 1 and 4 mm.

According to one embodiment, the depth of the peripheral hollow is comprised between 50 and 150 μm.

According to one embodiment, the rounded shape of the hollow has a radius of curvature comprised between 1 and 10 mm, in particular in the range of 5 mm.

According to one embodiment, each integrated circuit wafer comprises a first portion including electronic components and a second portion including interconnection networks integrated into one or more dielectric layers, the interconnection networks extending from said electronic components to the assembly face of this integrated circuit wafer, the interconnection networks of the two integrated circuit wafers being electrically connected via the two assembly faces.

According to one embodiment, said depth is such that the hollow partially extends into the first portion and extends into the second portion of the first wafer.

### BRIEF DESCRIPTION OF THE DRAWINGS

Other advantages and features of the invention will appear on examining the detailed description of embodiments and implementations, without limitation, and of the appended drawings in which:

FIG. 1 illustrates an implementation of a method for assembling two integrated circuit wafers;

FIG. 2 illustrates wafers electrically connected to each other via their assembly faces; and

FIGS. 3 to 6 schematically represent all or part of the two integrated circuit wafers without detailing the individual 3D structures, wherein FIG. 3 illustrates a sectional view of a section of the first wafer such that only one side of the integrated circuit wafer is represented, wherein FIG. 4 illustrates removal of material by abrasion to obtain a peripheral hollow in the peripheral zone of the integrated circuit wafer, wherein FIG. 5 illustrates the polishing machine comprising at least one abrasive belt configured to be capable of being applied against the perimeter of the assembly face of the first wafer, wherein FIG. 6 illustrates the bonding by molecular adhesion to form bonds between the dielectric layer of the second portion of the first wafer and the dielectric layer of the second portion of the second wafer.

### DETAILED DESCRIPTION OF EMBODIMENTS

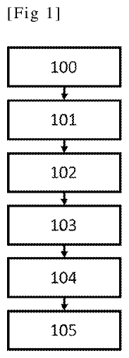

FIG. 1 illustrates an implementation of a method for assembling two integrated circuit wafers W1, W2. Such an assembly method is used to assemble two integrated circuit wafers W1, W2 stacked on top of each other so as to ultimately obtain an assembly example such as that illustrated in FIG. 6.

The assembly of the wafers W1, W2 can be permanent or temporary. In particular, a permanent assembly can be implemented to obtain an electronic structure in which the wafers are stacked. These wafers W1, W2 then respectively have assembly faces FINT1, FINT2 assembled against each other (FIG. 6).

The assembly can be carried out such that the wafers W1, W2 are electrically connected to each other via their assembly faces as illustrated very schematically in the lower portion of FIG. 2. In particular, each wafer W1, W2 can have electrically conductive tracks and/or electrically conductive contacts on their assembly face. In order to electrically connect the two wafers W1, W2, the latter are assembled by disposing the conductive tracks and/or the conductive contacts of one wafer opposite to and in contact with the conductive tracks and/or the conductive contacts of the other wafer.

The assembly of the integrated circuit wafers is then a 3D assembly which has electronic structures called 3D (“three-dimensional”) electronic structures, each including a chip from a first wafer assembled with a chip of a second wafer. The different 3D structures are mutually separated by the cutting lines.

Such a 3D structure allows reducing the lengths of the electrical interconnections between the two chips which compose it, so as to improve its performance in terms of speed.

The assembly of the integrated circuit wafers can then be cut so as to obtain the different 3D structures each including two electronic chips stacked on top of each other.

As indicated above, the use of different integrated circuit wafers allows distributing functions to each chip of a 3D structure. A first wafer can in particular be used to produce integrated circuits implementing an analogue portion of the electronic structures and a second wafer can be used to produce integrated circuits implementing a digital portion of the structures. For example, the first wafer W1 can be used to produce arrays of detectors of image sensors and the second wafer W2 can be used to produce integrated circuits implementing a digital processing of the data generated from these detector arrays.

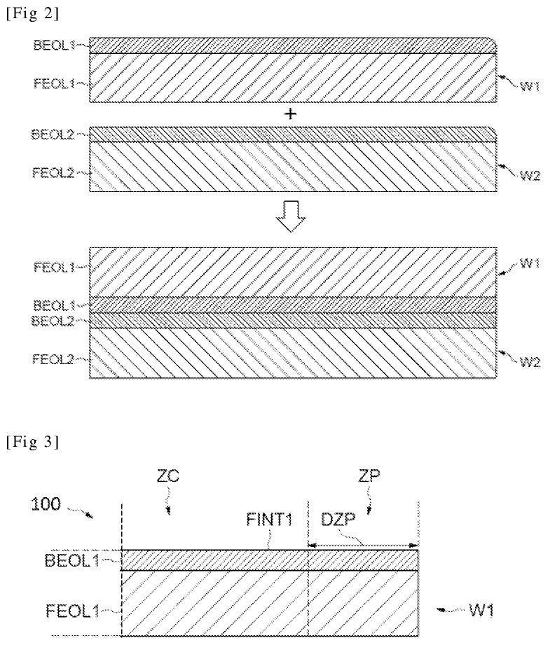

FIGS. 3 to 6 schematically represent all or part of the two integrated circuit wafers W1 and W2 without detailing the individual 3D structures.

More particularly, as illustrated in FIG. 2, each wafer comprises a first “FEOL” (acronym of the expression “Front End Of Line”) portion in which the electronic components of the chips are formed.

Each integrated circuit wafer also comprises a second “BEOL” (acronym of the expression “Back End Of Line”) portion including interconnection networks integrated in one or more dielectric layers. This second “BEOL” portion extends from the first FEOL portion to the assembly face of the integrated circuit wafer. In particular, the interconnection networks of the second BEOL portion extend from the electronic components of the first FEOL portion to the respective assembly face of the integrated circuit wafers.

More particularly, the first wafer W1 comprises a first portion FEOL1 and a second portion BEOL1 which extends to the assembly face FINT1 of the first wafer W1.

The second integrated circuit wafer W2 comprises a first portion FEOL2 and a second portion BEOL2 up to the assembly face FINT2 of the second wafer W2 (FIG. 6).

Moreover, each wafer has a perimeter laterally delimiting the wafer. In particular, the first wafer W1 has (FIG. 3) a main zone ZC and a peripheral zone ZP extending around the main zone to the perimeter of the wafer. FIG. 3 illustrates only a sectional view of a section of the first wafer W1, such that only one side of the integrated circuit wafer is represented. The main zone ZC of the first wafer W1 comprises all functional elements of the first wafer, that is to say the electronic components and the interconnection networks. The peripheral zone ZP is itself devoid of functional elements of the first wafer. The peripheral zone ZP can extend for example over a distance D1 comprised between 1 and 4 mm from the perimeter of the wafer W1, for example in the range of 3 mm.

The perimeter of each wafer can be rounded so that each wafer has an edge roll-off on the peripheral zone thereof. The edge roll-off corresponds to a drop in the height of the assembly face in the peripheral zone of the wafer relative to the main zone of the wafer.

The assembly method is used to carry out a hybrid bonding allowing creating bonds between the dielectric layers of the portions BEOL1 and BEOL2 of the integrated circuit wafers W1, W2 and bonds between the conductive tracks on the assembly face FINT1 of the wafer W1 and the conductive tracks on the assembly face FINT2 of the wafer W2.

As illustrated in FIG. 1, the method comprises obtaining 100 the first integrated circuit wafer W1 and the second integrated circuit wafer W2.

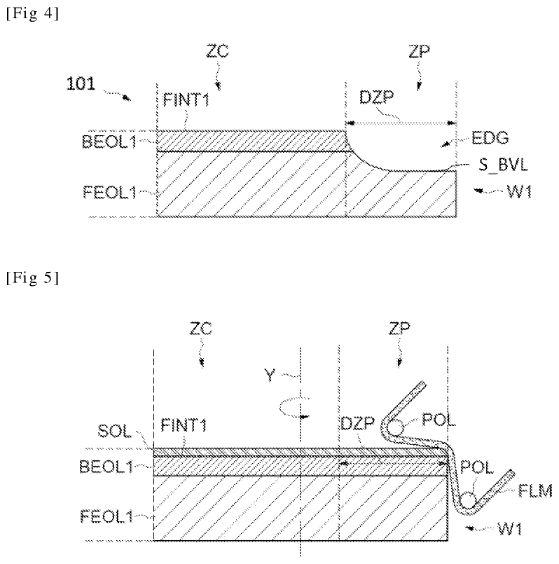

The method then comprises a removal of material by abrasion 101 of a portion of the perimeter of the assembly face of the first wafer W1. The removal of material by abrasion 101 allows hollowing the assembly face FINT1 from the perimeter of the first wafer W1 so as to hollow the assembly face FINT1 in the peripheral zone ZP of the first wafer W1 from the perimeter thereof. Thus, the removal of material by abrasion 101 allows obtaining a peripheral hollow EDG in the peripheral zone ZP of the integrated circuit wafer W1, as illustrated in FIG. 4. The hollow partially extends into the first portion FEOL1 and extends into the second portion BEOL1 of wafer W1.

In particular, the hollow EDG has a surface S_BVL extending from the assembly face FINT1 to the perimeter of the wafer W1. The surface S_BVL of the hollow has a rounded shape from the assembly face FINT1 of the first wafer W1 to a given depth in the first wafer W1 then is planar and parallel to the assembly face FINT1 from this depth to the perimeter of the first integrated circuit wafer FINT1.

More particularly, the hollow EDG is formed over a depth DEVD comprised between 50 and 150 μm, in particular in the range of 100 μm. The hollow EDG extends into the peripheral zone ZP of the wafer W1. The hollow EDG therefore extends from the perimeter of the wafer W1 over a distance DZP comprised between 1 and 4 mm, in particular in the range of 3 mm.

Furthermore, the surface S_BVL of the hollow EDG has, at the intersection between this surface S_BVL and the assembly face FINT1, a tangent which is at least substantially orthogonal to the assembly face FINT1. For example, the angle between this tangent and the assembly face FINT1 is comprised between 5 and 20 degrees.

In particular, the rounded shape of the hollow has a radius of curvature comprised between 1 and 10 mm, in particular in the range of 5 mm.

The removal 101 can be carried out by a polishing machine. The polishing machine comprises a support platform (not represented) which can be driven in rotation on itself about an axis (Y) orthogonal to this support platform and passing through the centre thereof.

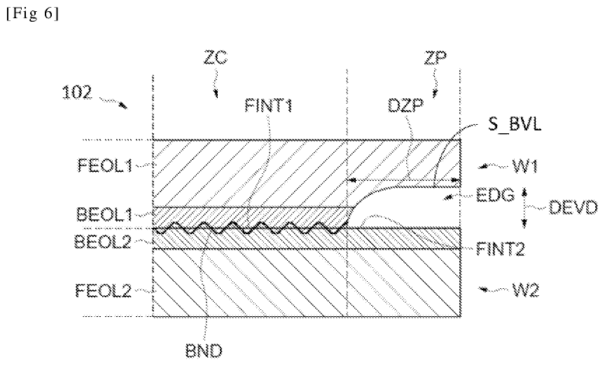

As illustrated in FIG. 5, the polishing machine comprises at least one abrasive belt FLM configured to be capable of being applied against the perimeter of the assembly face FINT1 of the first wafer W1.

In particular, each belt FLM has an abrasive face. This abrasive face can be placed against the perimeter of the assembly face FINT of the first wafer W1. In order to give it an abrasive property, diamonds are bonded on the abrasive face. These diamonds allow removing material from the first wafer W1 when the belt is driven in displacement.

Each belt FLM is configured to be unwound, that is to say driven in translation along its longitudinal direction, against the perimeter of the first wafer W1 on the assembly face FINT1 of the peripheral zone ZP so as to hollow the first wafer W1.

In order to form the peripheral hollow EDG, each abrasive belt FLM is brought into contact with the perimeter of the assembly face FINT1 and unrolled while rotating the first wafer W1 by driving the support platform in rotation.

The removal by abrasion of a portion of the assembly face FINT1 in the peripheral zone ZP of the first wafer W1 allows eliminating the edge roll-off of the first wafer W1. Furthermore, the removal by abrasion allows forming the peripheral hollow EDG having a rounded profile which limits, or even prevents, the appearance of defects on the periphery of the main zone ZC, such as those which may appear at the abrupt cut performed during mechanical trimming in the prior art.

The method then comprises a bonding 102 by molecular adhesion (also known as “fusion bonding”) of the assembly face FINT1 of the first wafer of W1 to the assembly face FINT2 of the second wafer W2.

As illustrated in FIG. 6, the bonding 102 by molecular adhesion allows forming bonds BND between the dielectric layer of the second portion BEOL1 of the first wafer W1 and the dielectric layer of the second portion BEOL2 of the second wafer W2.

The absence of defects on the periphery of the main zone ZC of the wafer W1 following the removal 101 by abrasion of a portion of the peripheral zone ZP carried out to eliminate the edge roll-off of the wafer W1 allows improving the bonding 102 by molecular adhesion.

The method then comprises a control 103 of the bonding 102 by molecular adhesion of the two wafers W1, W2. This control 103 allows checking that the bonding 102 by molecular adhesion of the two wafers W1, W2 has been carried out correctly. This control is carried out for example by an analysis of the assembly by acoustic waves in an aqueous medium. In particular, if the control 103 detects that the assembly is non-compliant, then the wafers can be peeled off to perform the removal 101 again before rebonding the two integrated circuit wafers by molecular adhesion.

This control 103 can be easily carried out following the bonding 102 by molecular adhesion due to the shape of the peripheral hollow EDG which prevents a penetration of moisture from the aqueous medium between the wafers W1, W2 which could lead to bonding defects. In particular, as seen previously, the surface S_BVL of the peripheral hollow EDG has, at the intersection between this surface S_BVL and the assembly face FINT1, a tangent which is at least substantially orthogonal to the assembly face FINT1 of the integrated circuit wafer W1. This tangent is also at least substantially orthogonal to the assembly face FINT2 of the integrated circuit wafer W2 once the bonding 102 by molecular adhesion has been carried out. In this manner, the periphery of the main zone ZC of the wafer W1 is indeed in contact with the wafer W2. The moisture of the aqueous medium cannot therefore penetrate between the two wafers W1, W2 during the control 103.

Controlling the bonding 102 by molecular adhesion at this stage of the method allows detecting defects in the bonding while it is still possible to peel off the two integrated circuit wafers W1, W2 before repeating the bonding. Thus, the detection of bonding defects at this stage of the method allows avoiding scrapping the two bonded integrated circuit wafers.

Furthermore, controlling the bonding 102 at this stage of the method allows avoiding implementing a thermocompression following the bonding by molecular adhesion. Indeed, the thermocompression conventionally used to improve the bonding of the two integrated circuit wafers is useless here because the quality of the bonding 102 by molecular adhesion has already been controlled.

The method then comprises an anneal 104. The anneal 104 allows creating covalent bonds BND between the conductive tracks on the assembly face FINT1 of the wafer W1 and the conductive tracks on the assembly face FINT2 of the wafer W2. The two integrated circuit wafers W1, W2 are then electrically connected. The anneal 104 also allows sealing the assembly of the two wafers W1, W2. The wafers W1, W2 can no longer be disassembled following this anneal 104. The anneal can be carried out at a temperature comprised between 200° C. and 450° C. in particular in the range of 350° C. for a period comprised between 1 and 4 hours in particular in the range of 2 hours.

The method then comprises a control 105 allowing checking the conformity of the assembly of the wafers W1, W2. In particular, the control 105 allows in particular checking the conformity of the bonds BND formed during the anneal 104.

The assembly of the integrated circuit wafers W1, W2 can then be cut to obtain the different 3D electronic structures each including several superimposed integrated circuits.

Such a method for assembling integrated circuit wafers has the advantage of being rapid compared to the known assembly methods. Indeed, such a method does not require thermocompression between the bonding 102 by molecular adhesion and the anneal 104. Furthermore, the bonding 102 by adhesion being improved, it is possible to more quickly control the conformity of the assembly of the integrated circuit wafers W1, W2.

Such an assembly method also has the advantage of reducing the scrapping of integrated circuit wafers following non-reversible assembly defects. Such an assembly method therefore allows reducing the manufacturing costs of superposed electronic chips.

The previously described assembly method allows obtaining an assembly of a first wafer W1 and a second wafer W2 of integrated circuits which are stacked on top of each other, as illustrated in FIG. 6.

Characteristics of an assembly of integrated circuit wafers W1 and W2 are reminded below according to one embodiment of the invention, as illustrated in this FIG. 6

The first wafer W1 and the second wafer W2 each comprise a first portion FEOL1, FEOL2 which includes electronic components and a second portion BEOL1, BEOL2 which includes interconnection networks integrated into one or more dielectric layers. The wafers W1 and W2 also each include an assembly face FINT1 and FINT2. The interconnection networks of the second portions BEOL1, BEOL2 extend, in each of the wafers W1, W2, from the electronic components to the respective assembly face of each wafer W1, W2.

The assembly face FINT2 of the second wafer W2 is bonded to the assembly face FINT1 of the first wafer W1. The interconnection networks of the first wafer W1 and of the second wafer W2 are electrically connected via the assembly faces FINT1 and FINT2, in particular via covalent bonds BND between conductive tracks on the assembly face FINT1 of the integrated circuit wafer W1 and conductive tracks on the assembly face FINT2 of the integrated circuit wafer W2

The first integrated circuit wafer W1 further includes a peripheral hollow EDG. The peripheral hollow EDG extends in a peripheral zone ZP of the first integrated circuit wafer and, in particular, from the perimeter of the first integrated circuit wafer W1 over a distance DZP comprised between 1 and 4 mm. Furthermore, the hollow EDG has a depth DEVD comprised between 50 and 150 μm, for example in the range of 100 μm.

The peripheral hollow EDG has a surface S_BVL which extends from the assembly face FINT1 to the perimeter of the first wafer W1. The surface S_BVL of the hollow has a rounded shape from the assembly face FINT1 of the first wafer W1 to a depth in the first wafer W1. In particular, the rounded shape of the hollow EDG has a radius of curvature comprised between 1 and 10 mm, in particular in the range of 5 mm.

The surface S_BVL of the hollow EDG is, furthermore, planar and parallel to the assembly face FINT1 from this depth to the perimeter of the first integrated circuit wafer W1. The surface S_BVL of the hollow also presents, at the intersection between this surface S_BVL and the assembly face FINT1, a tangent oriented relative to the assembly face FINT1 at an angle comprised between 5 and 20 degrees.

What is claimed is:

1. A method for assembling two integrated circuit wafers, the method comprising:
removing by abrasion of a portion of an assembly face of a first wafer on a perimeter of the first wafer; and
bonding the assembly face of the first wafer to an assembly face of a second integrated circuit wafer.

2. The method according to claim 1, wherein the removing forms a peripheral hollow having a surface extending from the assembly face to the perimeter of the first wafer, the surface of the hollow having a rounded shape from the assembly face of the first wafer to a depth in the first wafer then being planar and parallel to the assembly face from this depth to the perimeter of the first wafer.

3. The method according to claim 2, wherein the hollow extends from the perimeter of the first wafer over a distance comprised between 1 and 4 mm.

4. The method according to claim 2, wherein the hollow is formed over a depth comprised between 50 and 150 μm.

5. The method according to claim 2, wherein the rounded shape of the hollow has a radius of curvature comprised between 1 and 10 mm.

6. The method according to claim 2, wherein the surface of the hollow has, at the intersection between this surface and the assembly face, a tangent oriented relative to the assembly face at an angle comprised between 5 and 20 degrees.

7. The method according to claim 1, wherein the removing is carried out using at least one abrasive belt placed against the assembly face on the perimeter of the first wafer while driving the first wafer in rotation.

8. The method according to claim 7, wherein the surface of the abrasive belts has an abrasive face including abrasive diamonds.

9. The method according to claim 1, wherein the bonding is a bonding by molecular adhesion.

10. The method according to claim 1, further comprising controlling a conformity of the bonding.

11. The method according to claim 1, wherein each integrated circuit wafer comprises a first portion including electronic components and a second portion including interconnection networks integrated in one or more dielectric layers, the interconnection networks extending from the electronic components to the assembly face of this integrated circuit wafer, the interconnection networks of the two integrated circuit wafers being adapted to be electrically connected via the two assembly faces once the two integrated circuit wafers have been assembled.

12. A method for assembling two integrated circuit wafers, the method comprising:
removing by abrasion of a portion of an assembly face of a first wafer on a perimeter of the first wafer;
bonding the assembly face of the first wafer to an assembly face of a second integrated circuit wafer; and
annealing following the bonding.

13. The method according to claim 12, wherein the annealing is carried out after controlling the conformity of the bonding.

14. The method according to claim 12, further comprising controlling the assembly of the two integrated circuit wafers after the annealing.

15. An assembly of two integrated circuit wafers comprising:
a first wafer including an assembly face and a peripheral hollow having a surface extending from the assembly face to the perimeter of the first wafer, the surface of the hollow having a rounded shape from the assembly face of the first wafer to a depth in the first wafer then being planar and parallel to the assembly face from this depth to the perimeter of the first wafer; and
a second integrated circuit wafer including an assembly face bonded to the assembly face of the first wafer.

16. The assembly according to claim 15, wherein the surface of the hollow has, at the intersection between this surface and the assembly face, a tangent oriented relative to the face at an angle comprised between 5 and 20 degrees.

17. The assembly according to claim 15, wherein the hollow extends from the perimeter of the first wafer over a distance comprised between 1 and 4 mm.

18. The assembly according to claim 15, wherein the depth of the peripheral hollow is comprised between 50 and 150 μm.

19. The assembly according to claim 15, wherein the rounded shape of the hollow has a radius of curvature comprised between 1 and 10 mm, in particular in the range of 5 mm.

20. The assembly according to claim 15, wherein each integrated circuit wafer comprises a first portion including electronic components and a portion including interconnection networks integrated into one or more dielectric layers, the interconnection networks extending from the electronic components to the assembly face of this integrated circuit wafer, the interconnection networks of the two integrated circuit wafers being electrically connected via the two assembly faces.
